(19) United States
(12) Patent Application Publication
(10) Pub. No.: US 2023/0360909 A1
(43) Pub. Date: Nov. 9, 2023

(54) EPITAXIAL STRUCTURE AND METHOD OF MANUFACTURING THE SAME

(71) Applicant: GLOBALWAFERS CO., LTD., Hsinchu City (TW)

(72) Inventors: PO-JUNG LIN, Hsinchu City (TW); HAN-ZONG WU, Hsinchu City (TW)

(73) Assignee: GLOBALWAFERS CO., LTD., Hsinchu City (TW)

(21) Appl. No.: 18/104,443

(22) Filed: Feb. 1, 2023

Related U.S. Application Data
(60) Provisional application No. 63/338,545, filed on May 5, 2022.

(51) Int. Cl. H01L 21/02; C30B 25/18; C30B 29/40; C30B 29/68; C23C 16/30; C23C 16/02

(52) U.S. Cl. CPC H01L 21/02458; H01L 21/02378; H01L 21/02428; H01L 21/02447; H01L 21/0254; C30B 25/183; C30B 29/403; C30B 29/406; C30B 29/68; C23C 16/303; C23C 16/0272; H01L 21/02631; H01L 21/0262

(57) ABSTRACT

A method of manufacturing an epitaxial structure includes steps of: A: provide a silicon carbide (SiC) substrate, wherein a silicon face (Si-face) of the SiC substrate is taken as a growth face having an off-angle relative to the Si-face of the SiC substrate; B: deposit a nitride angle adjustment layer having a thickness less than 50 nm on the growth face of the SiC substrate through physical vapor deposition (PVD); C: deposit a first group III nitride layer on the nitride angle adjustment layer; and D: deposit a second group III nitride layer on the first group III nitride layer. Through the method of manufacturing the epitaxial structure, when the silicon face of the silicon carbide substrate has the off-angle, the problem of a poor epitaxial quality of the first group III nitride layer and a poor epitaxial quality of the second group III nitride layer could be effectively relieved.

### BACKGROUND OF THE INVENTION

### Technical Field

The present invention relates generally to a method of manufacturing an epitaxial structure, and more particularly to a method of forming a group III nitride layer on a SiC substrate.

### Description of Related Art

It is known that group III-V semiconductors, for example, gallium nitride (GaN), are widely applied to different electronic structures, wherein one of the major applicable fields is a High Electron Mobility Transistor (HEMT). The HEMT is a transistor having a two dimensional electron gas (2-DEG) that is located close to a heterojunction of two materials with different energy gaps. As the HEMT makes use of the 2-DEG having a high electron mobility as a carrier channel of the transistor instead of a doped region, the HEMT has features of a high breakdown voltage, the high electron mobility, a low on-resistance, and a low input capacitance.

A HEMT is used as an example for illustration. Generally, in order to reduce a lattice mismatch between a silicon carbide (SiC) substrate and a gallium nitride (GaN) layer, an aluminum nitride (AlN) layer serving as a nucleation layer is grown on the SiC substrate through metal-organic chemical vapor deposition (MOCVD) before growing the GaN layer. However, when a silicon face of the SiC substrate having an off-angle is taken as a growth face for performing epitaxy of the AN layer, an off-angle property of the SiC substrate extends to the AN layer due to features of the MOCVD process, making an epitaxial quality to be poor, thereby affecting properties and performances of a component. Therefore, how to provide a method of manufacturing an epitaxial structure, which could provide a better epitaxial quality when a silicon face of a SiC substrate having an off-angle is taken as a growth face for epitaxy of a group III nitride layer, is a problem needed to be solved in the industry.

### BRIEF SUMMARY OF THE INVENTION

In view of the above, the primary objective of the present invention is to provide a method of manufacturing an epitaxial structure, which could provide a better epitaxial quality when a silicon face of a silicon carbide (SiC) substrate having an off-angle is taken as a growth face for epitaxy of a group III nitride layer.

The present invention provides a method of manufacturing an epitaxial structure including steps of: A: provide a silicon carbide (SiC) substrate, wherein a silicon face (Si-face) of the SiC substrate is taken as a growth face, and the growth face has an off-angle relative to the Si-face of the SiC substrate; B: deposit a nitride angle adjustment layer having a thickness less than 50 nm on the growth face of the SiC substrate through physical vapor deposition (PVD); C: deposit a first group III nitride layer on the nitride angle adjustment layer; and D: deposit a second group III nitride layer on the first group III nitride layer.

The present invention further provides an epitaxial structure including a silicon carbide (SiC) substrate, a nitride angle adjustment layer, a first group III nitride layer, and a second group III nitride layer. A silicon face (Si-face) of the SiC substrate is taken as a growth face, and the growth face has an off-angle greater than zero degree relative to the Si-face of the SiC substrate. The nitride angle adjustment layer is located on the growth face of the SiC substrate, is deposited on the growth face of the SiC substrate through physical vapor deposition (PVD), and has a thickness less than 50 nm. The first group III nitride layer is located on the nitride angle adjustment layer. The second group III nitride layer is located on the first group III nitride layer.

With the aforementioned design, by forming the nitride angle adjustment layer between the SiC substrate and the first group III nitride layer through physical vapor deposition (PVD), the problem of the poor epitaxial quality of the first group III nitride layer and the poor epitaxial quality of the second group III nitride layer due to the off-angle property of the SiC substrate extending to the first group III nitride layer could be relieved.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a flowchart of the method of manufacturing the epitaxial structure according to an embodiment of the present invention;

FIG. 2 is a schematic view showing the epitaxial structure according to another embodiment of the present invention;

FIG. 3 is a schematic view showing the epitaxial structure according to an embodiment of the present invention;

FIG. 4A is an atomic force microscope photograph showing the surface topography of the epitaxial structure according to a first comparative example of the present invention;

FIG. 4B is an atomic force microscope photograph showing the surface topography of the epitaxial structure according to a second comparative example of the present invention;

FIG. 4C is an atomic force microscope photograph showing the surface topography of the epitaxial structure according to an embodiment of the present invention;

FIG. 5A is a schematic view showing the interface between the silicon carbide substrate and the first group III nitride layer made of AlN according to the second comparative example of the present invention; and

FIG. 5B is a schematic view showing the interface between the silicon carbide substrate and the nitride angle adjustment layer made of AlN according to an embodiment of the present invention.

### DETAILED DESCRIPTION OF THE INVENTION

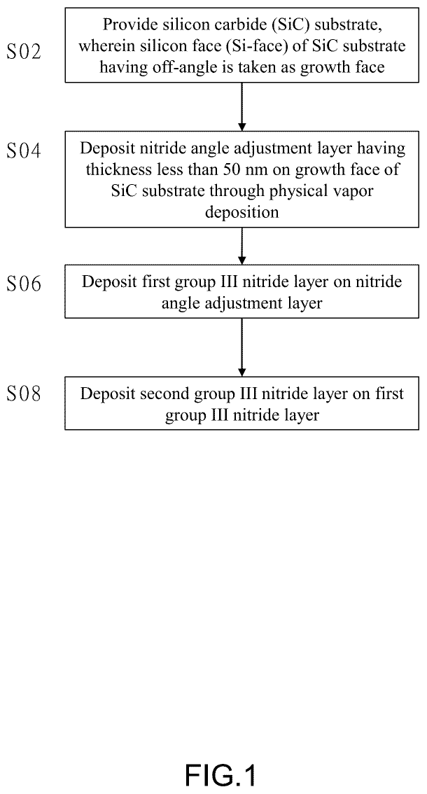

A method of manufacturing an epitaxial structure according to an embodiment of the present invention is illustrated in a flowchart as shown in FIG. 1 and includes steps of:
step S02: provide a silicon carbide (SiC) substrate 10, wherein a silicon face (Si-face) of the SiC substrate 10 is taken as a growth face, and the growth face has an off-angle relative to the Si-face of the SiC substrate; the off-angle is an angle between the growth face and a <0001> axial direction of a silicon carbide (0001) face and does not differ between positivity and negativity;
step S04: deposit a nitride angle adjustment layer 20 having a thickness less than 50 nm on the growth face of the SiC substrate through physical vapor deposition (PVD); in the current embodiment, the nitride angle adjustment layer 20 is aluminum nitride (AlN) or aluminum-gallium nitride (Al_{X}Ga_{1-X}N) and has a root mean square (RMS) roughness less than 5 nm;
step S06: deposit a first group III nitride layer 30 on the nitride angle adjustment layer 20; in the current embodiment, in the step S06, the first group III nitride layer 30 is deposited on the nitride angle adjustment layer 20 through metal-organic chemical vapor deposition (MOCVD); the first group III nitride layer 30 is aluminum nitride (AlN) or aluminum-gallium nitride (Al_{X}Ga_{1-X}N); a thickness of the first group III nitride layer 30 is between 50 nm and 95 nm, and an RMS roughness of the first group III nitride layer 30 is less than 3 nm; in view of the above, through the nitride angle adjustment layer 20, an epitaxial quality of the first group III nitride layer 30 could be effectively increased;
step S08: deposit a second group III nitride layer 40 on the first group III nitride layer 30; in the current embodiment, in the step S08, the second group III nitride layer 40 is deposited on the first group III nitride layer 30 through MOCVD; the second group III nitride layer 40 is gallium nitride (GaN) and has an RMS roughness less than 1.5 nm; in view of the above, through the nitride angle adjustment layer 20, an epitaxial quality of the second group III nitride layer 40 could be effectively increased.

The method of manufacturing the epitaxial structure includes analyzing the nitride angle adjustment layer 20, the first group III nitride layer 30, and the second group III nitride layer 40 through X-ray diffraction analysis, wherein a full width at half maximum (FWHM) of the nitride angle adjustment layer 20 is between 1500 arcsec and 10000 arcsec, a FWHM of a (002) crystal plane of the first group III nitride layer 30 is between 300 arcsec and 600 arcsec, and a FWHM of a (002) crystal plane of the second group III nitride layer 40 is less than 200 arcsec. In view of the above, through the nitride angle adjustment layer 20, the epitaxial quality of the first group III nitride layer 30 and the epitaxial quality of the second group III nitride layer 40 could be effectively increased.

In an embodiment, the nitride angle adjustment layer 20 having a thickness less than 50 nm corresponds to the SiC substrate 10 with the Si-face having the off-angle greater than 4 degrees, wherein the FWHM of the nitride angle adjustment layer 20 is 20 times greater than the FWHM of the first group III nitride layer 30 and is between 6000 arcsec and 10000 arcsec; in another embodiment, the nitride angle adjustment layer 20 having the thickness less than 25 nm corresponds to the SiC substrate 10 with the Si-face having the off-angle greater than or equal to 1 degree and less than or equal to 4 degrees, wherein the FWHM of the nitride angle adjustment layer 20 is 10 times greater than the FWHM of the first group III nitride layer 30 and is between 3000 arcsec and 6000 arcsec; in still another embodiment, the nitride angle adjustment layer 20 having the thickness less than 10 nm corresponds to the SiC substrate 10 with the Si-face having the off-angle less than 1 degree, wherein the FWHM of the nitride angle adjustment layer 20 is 5 times greater than the FWHM of the first group III nitride layer 30 and is between 1500 arcsec and 3000 arcsec; in this way, the nitride angle adjustment layer 20 having different thicknesses corresponds to the SiC substrate with the Si-face having the off-angle in different degrees, thereby increasing the epitaxial quality of the first group III nitride layer 30 and the epitaxial quality of the second group III nitride layer 40.

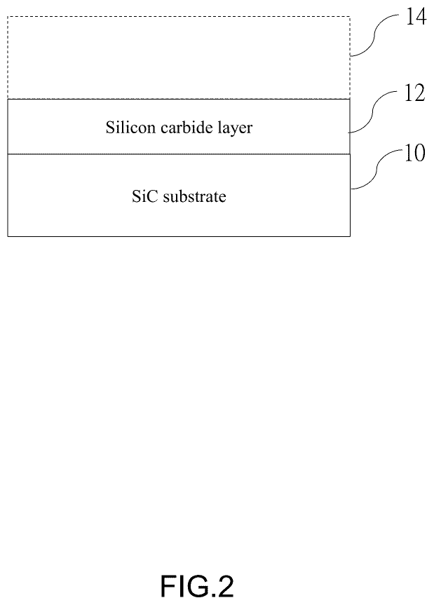

In another embodiment, the step S02 further includes depositing a silicon carbide layer 12 on the growth face of the SiC substrate 10 through MOCVD. An off-angle of a growth face of the silicon carbide layer 12 relative to a silicon face of the silicon carbide layer 12 is the same as the off-angle of the growth face of the SiC substrate 10 relative to the Si-face of the SiC substrate 10. The silicon carbide layer 12 is located between the SiC substrate 10 and the nitride angle adjustment layer 20. When the off-angle of the silicon face of the silicon carbide layer 12 is 4 degrees, a breakdown voltage of the silicon carbide layer 12 is greater than 600 V, thereby the silicon carbide layer 12 could be adapted to form different electronic components 14. For example, referring to FIG. 2, the SiC substrate 10 having the silicon carbide layer 12 forms the electronic components 14 through subsequent processing, for instance, a Metal-Oxide-Semiconductor Field-Effect Transistor (MOSFET), a Schottky barrier diode (SBD), or a High Electron Mobility Transistor (HEMT) having the first group III nitride layer 30 made of aluminum nitride (AlN) and the second group III nitride layer 40 made of gallium nitride (GaN) as examples.

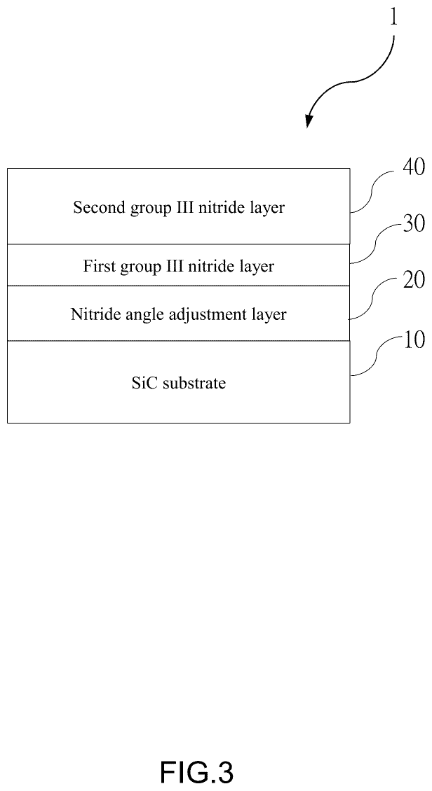

An epitaxial structure 1 manufactured through the aforementioned method of manufacturing the epitaxial structure is illustrated in FIG. 3 and includes the silicon carbide (SiC) substrate 10, the nitride angle adjustment layer 20, the first group III nitride layer 30, and the second group III nitride layer 40. The silicon face (Si-face) of the SiC substrate 10 is taken as a growth face, wherein the growth face has an off-angle greater than 0 degree relative to the Si-face of the SiC substrate 10. The nitride angle adjustment layer 20 is located on the growth face of the SiC substrate 10, is connected to the growth face of the SiC substrate 10, and is deposited to form on the growth face of the SiC substrate 10 through physical vapor deposition (PVD). The first group III nitride layer 30 is located on the nitride angle adjustment layer 20. The second group III nitride layer 40 is located on the first group III nitride layer 30.

Referring to Table 1, two comparative examples and an embodiment of the present invention are illustrated as following. A first comparative example is to deposit a first group III nitride layer made of AlN and a second group III nitride layer made of GaN in order through metal-organic chemical vapor deposition (MOCVD) on a silicon face of a silicon carbide substrate having an off-angle of 0.5 degrees, and then analyze and measure a surface topography through atomic force microscope (AFM). A second comparative example is to deposit a first group III nitride layer made of AlN and a second group III nitride layer made of GaN in order through metal-organic chemical vapor deposition (MOCVD) on a silicon face of a silicon carbide substrate having an off-angle of 4 degrees, and then analyze and measure a surface topography through atomic force microscope (AFM). Referring to results shown in Table 1, the larger the off-angle of the silicon face of the silicon carbide substrate, the poorer the root mean square (RMS) roughness performance.

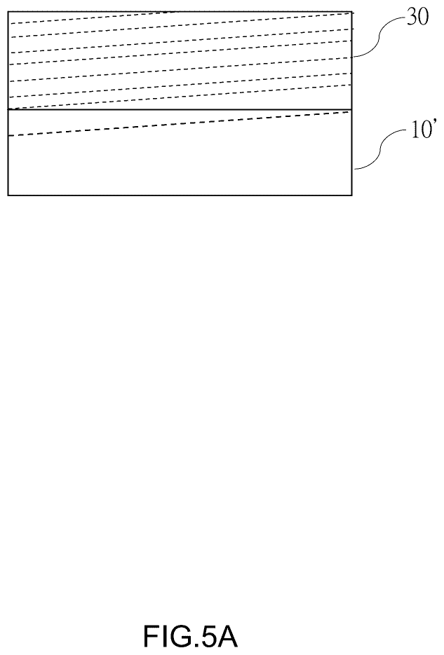

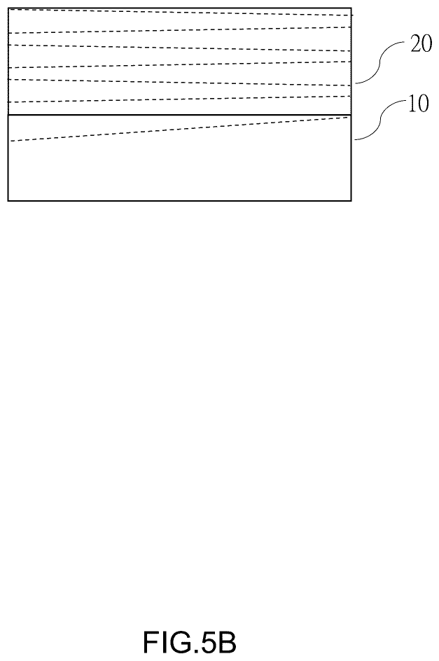

The difference between an epitaxial structure in the embodiment and an epitaxial structure in the first comparative example and an epitaxial structure in the second comparative example is that the epitaxial structure in the current embodiment is to deposit a nitride angle adjustment layer made of AlN through PVD between a silicon carbide substrate 10 and a first group III nitride layer made of AlN. As shown in Table 1, an RMS roughness performance of the epitaxial structure in the current embodiment is clearly better than the RMS roughness performance of the epitaxial structure in the second comparative example. Additionally, referring to FIG. 5A and FIG. 5B, FIG. 5A is a schematic view showing an interface between a silicon carbide substrate 10′ and the first group III nitride layer made of AlN according to the second comparative example of the present invention and shows that an off-angle property of the silicon carbide substrate 10′ extends to the first group III nitride layer made of AlN, wherein the first group III nitride layer made of AlN has an off-angle the same as the off-angle of 4 degrees of the silicon face of the silicon carbide substrate 10′. FIG. 5B is a schematic view showing an interface between the silicon carbide substrate 10 and the nitride angle adjustment layer made of AlN according to the embodiment of the present invention and shows that through forming the nitride angle adjustment layer made of AlN via PVD, an angle adjustment process is automatically performed in the nitride angle adjustment layer made of AlN for adjusting an off-angle property of the silicon carbide substrate 10. In this way, an epitaxial quality of the first group III nitride layer and an epitaxial quality of the second group III nitride layer deposited on the nitride angle adjustment layer made of AlN could be effectively improved. In other words, through disposing the angle adjustment layer, the problem of the poor epitaxial quality of the second group III nitride layer on the silicon face of the silicon carbide substrate having the off-angle could be effectively relieved.

Referring to Table 1, compared to the second comparative example, an RMS roughness of the second group III nitride layer in the current embodiment improves from between −22.4 nm and 20 nm in the second comparative example to between −1.3 nm and 1.2 nm through disposing the angle adjustment layer, improving the RMS roughness by an order of magnitude. Additionally, as shown in Table 1, the first comparative example makes use of the silicon carbide substrate having the off-angle approaching to zero degree, an RMS roughness performance of the first comparative example is between −2.3 nm and 2.4 nm and is the same order of magnitude of the RMS roughness performance of the current embodiment, showing that through disposing the angle adjustment layer, the RMS roughness performance of the current embodiment using a substrate with an off-angle is close to an RMS roughness performance using a substrate with a small off-angle or without an off angle.

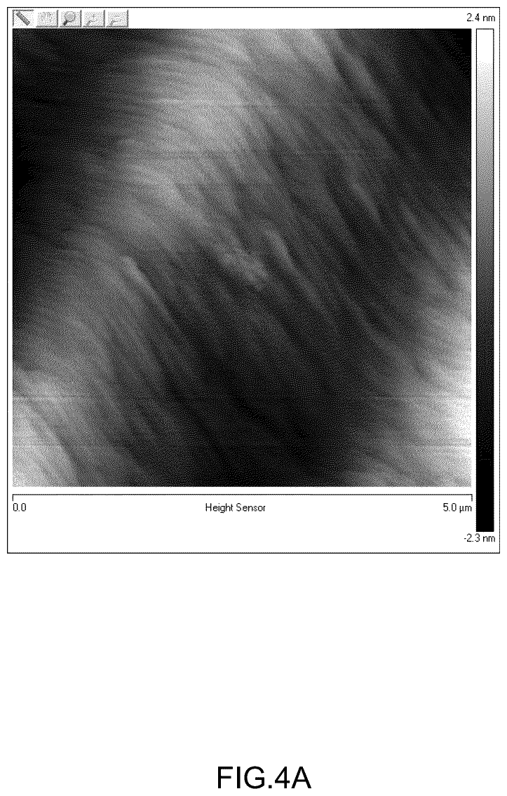

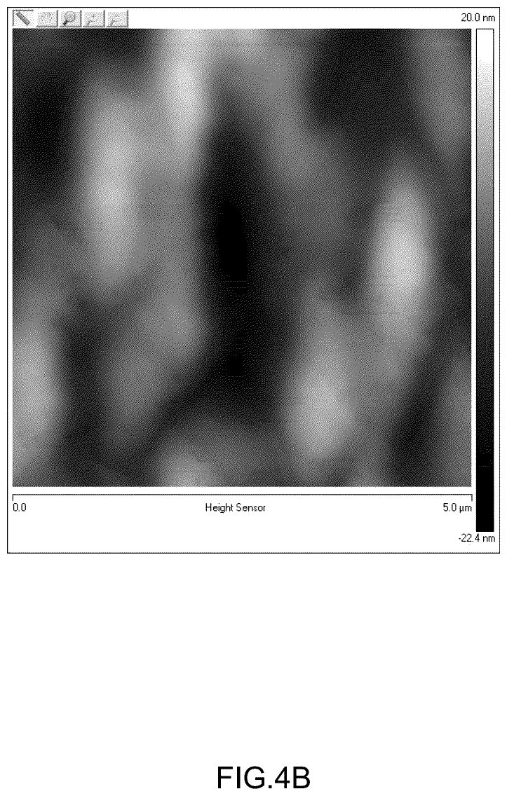

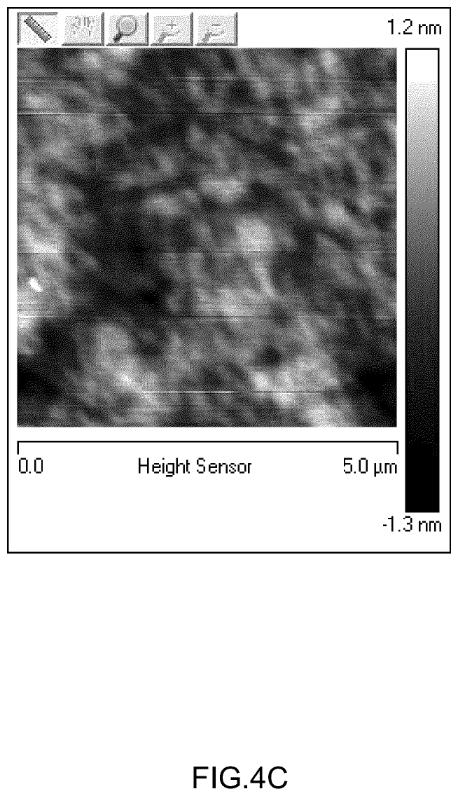

TABLE 1

| | | Angle | RMS | |
|---|---|---|---|---|
| | | adjustment | roughness | Surface |
| | Substrate | layer | (nm) | topography |
| The first | Silicon carbide substrate | No | Between −2.3 | Referring |
| comparative | having a silicon face with | | and 2.4 | to FIG. 4A |
| example | an off-angle of 0.5 degrees | | | |
| The second | Silicon carbide substrate | No | Between −22.4 | Referring |
| comparative | having a silicon face with | | and 20 | to FIG. 4B |
| example | an off-angle of 4 degrees | | | |
| The | Silicon carbide substrate | Yes | Between −1.3 | Referring |
| embodiment | having a silicon face with | | and 1.2 | to FIG. 4C |
| | an off-angle of 4 degrees | | | |

With the aforementioned design, by forming the nitride angle adjustment layer between the silicon carbide substrate and the first group III nitride layer through physical vapor deposition (PVD), the problem of the poor epitaxial quality of the first group III nitride layer and the poor epitaxial quality of the second group III nitride layer caused by the off-angle property of the silicon carbide substrate extending to the first group III nitride layer when the silicon face of the silicon carbide substrate has the off-angle could be effectively relieved.

It must be pointed out that the embodiments described above are only some preferred embodiments of the present invention. All equivalent structures and methods which employ the concepts disclosed in this specification and the appended claims should fall within the scope of the present invention.

What is claimed is:

1. A method of manufacturing an epitaxial structure, comprising steps of:
A: providing a silicon carbide (SiC) substrate, wherein a silicon face (Si-face) of the SiC substrate is taken as a growth face, and the growth face has an off-angle relative to the Si-face of the SiC substrate;
B: depositing a nitride angle adjustment layer having a thickness less than 50 nm on the growth face of the SiC substrate through physical vapor deposition (PVD);
C: depositing a first group III nitride layer on the nitride angle adjustment layer; and
D: depositing a second group III nitride layer on the first group III nitride layer.

2. The method as claimed in claim 1, wherein the off-angle is greater than 4 degrees.

3. The method as claimed in claim 2, further comprising analyzing the nitride angle adjustment layer and the first group III nitride layer through X-ray diffraction analysis, wherein a full width at half maximum (FWHM) of the nitride angle adjustment layer is greater than 6000 arcsec.

4. The method as claimed in claim 1, wherein the off-angle is between 1 degree and 4 degrees.

5. The method as claimed in claim 4, wherein the thickness of the nitride angle adjustment layer is less than 25 nm.

6. The method as claimed in claim 5, further comprising analyzing the nitride angle adjustment layer and the first group III nitride layer through X-ray diffraction analysis, wherein a full width at half maximum (FWHM) of the nitride angle adjustment layer is greater than 3000 arcsec.

7. The method as claimed in claim 1, wherein the off-angle is less than 1 degree.

8. The method as claimed in claim 7, wherein the thickness of the nitride angle adjustment layer is less than 10 nm.

9. The method as claimed in claim 8, further comprising analyzing the nitride angle adjustment layer and the first group III nitride layer through X-ray diffraction analysis, wherein a full width at half maximum (FWHM) of the nitride angle adjustment layer is greater than 1500 arcsec.

10. The method as claimed in claim 1, wherein the nitride angle adjustment layer is aluminum nitride (AlN) or aluminum-gallium nitride (Al_{X}Ga_{1-X}N).

11. The method as claimed in claim 1, wherein in the step C, the first group III nitride layer is deposited on the nitride angle adjustment layer through metal-organic chemical vapor deposition (MOCVD) and is aluminum nitride (AlN) or aluminum-gallium nitride (Al_{X}Ga_{1-X}N).

12. The method as claimed in claim 1, wherein the second group III nitride layer is gallium nitride (GaN).

13. The method as claimed in claim 1, wherein the step A comprises depositing a silicon carbide layer on the growth face of the SiC substrate; an off-angle of a growth face of the silicon carbide layer relative to a silicon face of the silicon carbide layer is the same as the off-angle of the growth face of the SiC substrate relative to the silicon face of the SiC substrate; the silicon carbide layer is located between the nitride angle adjustment layer and the SiC substrate.

14. An epitaxial structure, comprising:
a silicon carbide (SiC) substrate, wherein a silicon face (Si-face) of the SiC substrate is taken as a growth face, and the growth face has an off-angle greater than zero degree relative to the Si-face of the SiC substrate;
a nitride angle adjustment layer located on the growth face of the SiC substrate, deposited to form on the growth face of the nitride angle adjustment layer through physical vapor deposition (PVD), and having a thickness less than 50 nm;
a first group III nitride layer located on the nitride angle adjustment layer; and
a second group III nitride layer located on the first group III nitride layer.

15. The epitaxial structure as claimed in claim 14, wherein the off-angle is greater than 4 degrees, and a full width at half maximum (FWHM) of the nitride angle adjustment layer is greater than 6000 arcsec.

16. The epitaxial structure as claimed in claim 14, wherein the off-angle is greater than or equal to 1 degree and less than or equal to 4 degrees; the thickness of the nitride angle adjustment layer is less than 25 nm and a full width at half maximum (FWHM) of the nitride angle adjustment layer is greater than 3000 arcsec.

17. The method as claimed in claim 14, wherein the off-angle is less than 1 degree; the thickness of the nitride angle adjustment layer is less than 10 nm and a full width at half maximum (FWHM) of the nitride angle adjustment layer is greater than 1500 arcsec.

18. The method as claimed in claim 14, wherein the first group III nitride layer is deposited on the nitride angle adjustment layer through metal-organic chemical vapor deposition (MOCVD) and is aluminum nitride (AlN) or aluminum-gallium nitride (Al_{X}Ga_{1-X}N); the nitride angle adjustment layer is aluminum nitride (AlN) or aluminum-gallium nitride (Al_{X}Ga_{1-X}N); the second group III nitride layer is gallium nitride (GaN).

19. The method as claimed in claim 14, wherein the second group III nitride layer is gallium nitride (GaN) and has a root mean square (RMS) less than 1.5 nm.

20. The method as claimed in claim 14, wherein the second group III nitride layer is gallium nitride (GaN), and a full width at half maximum (FWHM) of a (002) crystal plane of the second group III nitride layer is less than 200 arcsec.
